(19) United States
(12) Patent Application Publication
(10) Pub. No.: US 2008/0024994 A1
(43) Pub. Date: Jan. 31, 2008

(54) COMBINATION HEAT SINK

(75) Inventor: Ming-Jen Cheng, Shulin City (TW)

Correspondence Address: BIRCH STEWART KOLASCH & BIRCH, PO BOX 747, FALLS CHURCH, VA, 22040-0747, US

(73) Assignee: BIN PEY CO., LTD

(21) Appl. No.: 11/491,988

(22) Filed: Jul. 25, 2006

(51) Int. Cl. H05K 7/20

(52) U.S. Cl. 361/710

(57) ABSTRACT

A combination heat sink formed of a plurality of radiation fins radially fastened together to show a circular configuration having a top rounded recess that is defined by a notch on each radiation fin for gathering currents of air for enabling gathered currents of air to be guided by a curved surface portion of each radiation fin to the outside of the heat sink to carry heat away from the heat sink rapidly and efficiently. Each radiation fin has a coupling portion so arranged that the radiation fins are fastened together by securing the coupling portion of one radiation fin to the coupling portion of another without the use of any external fastening means of tools.

### BACKGROUND OF THE INVENTION

1. Field of the Invention

The present invention relates a heat sink and more particularly, to a combination heat sink that has a top rounded recess defined by a notch of each radiation fin thereof and a curved surface portion on each radiation fin adapted to guide circulation of currents of air to dissipate heat rapidly.

2. Description of the Related Art

Following fast development of 3C (computer, communication and consumer electrics) and multimedia related industries the related hardware equipments are required to have a high operation power and speed. The internal processors, chips and other active component parts release much heat during operation. It is quite important to dissipate heat from the internal electronic devices rapidly during the operation of an electronic apparatus. Regularly, a heat sink is used and mounted on the surface of the heat generating electronic device to absorb heat from the heat generating electronic device, and a fan is controlled to cause currents toward the heat sink to dissipate heat from the heat sink.

Various heat sinks are commercially available. FIGS. 5 and 6 show an annular heat sink according to the prior art. According to this design, the heat sink A is comprised of a plurality of radiation fins A1 radially arranged together to constitute an annular structure. Each radiation fin A1 has a flat base A11, a top flange A12 at the top side of the flat base A11, a bottom flange A113 at the bottom side of the flat base A11, and a notch A14 on the top flange A12. The bottom flange A13 is smoothly arched in one direction. When the radiation fins A1 are radially arranged together, a retaining ring B is fastened to the notch A14 of each radiation fin A1 to hold the radiation fins A1 firmly together. When the heat sink A is assembled, the smoothly arched bottom flanges A13 of the radiation fins A1 define a bottom recess that fits a metal cone plate A2. This design of heat sink has numerous drawbacks as follows:
1. The use of the retaining ring B to secure the radiation fins A1 together greatly increases the manufacturing cost of the heat sink A. Further, it is requires much labor to fasten the retaining ring B to the notch A14 of each radiation fin A1.
2. The hollow center area of the heat sink A does not have wind resistant means to gather the currents of air from the external fan and to guide the currents of air over the surface of each radiation fin, resulting in low performance in heat dissipation.
3. Each radiation fin A1 of the heat sink A is a flat plane. When a rotating flow of air is passing from the external fan toward the heat sink A, the straight flat surfaces of the radiation fins cannot guide circulation of the rotating flow of air A1 through the gap between each two adjacent radiation fins A1 to carry heat away from the radiation fins A1 effectively.
4. The top flanges A12 of the radiation fins A1 impart a barrier to the currents of air from the external fan, blocking a part of outside cold air from passing through the gap in between each two adjacent radiation fins A1 and lowering the performance in heat dissipation.

Therefore, it is desirable to provide a heat sink that eliminates the aforesaid drawbacks.

### SUMMARY OF THE INVENTION

The present invention has been accomplished under the circumstances in view. It is the main object of the present invention to provide a combination heat sink, which can easily be assembled without the use of external fastening means of tools. It is another object of the present invention to provide a combination heat sink, which guides flowing of currents of air over the surface of each radiation fin to dissipate heat rapidly.

To achieve these and other objects of the present invention, the combination heat sink is comprised of a plurality of radiation fins radially fastened together to show a circular configuration having a top rounded recess. Each radiation fin has a flat base, a bonding portion extending from the bottom side of the flat base for bonding to a metal member, a curved surface portion extending from the front side of the flat base, a notch formed on the top side of the flat base adjacent to the curved surface portion, and a coupling portion extending from the front side of the curved surface portion opposite to the flat base at an angle. The coupling portions of the radiation fins are coupled to one another such that the notches of the radiation fins constitute a rounded recess at a top side of the heat sink. The rounded recess works to receive currents of air from an external fan and to guide currents of air evenly over the surface of each radiation fin toward the outside of the heat sink.

### BRIEF DESCRIPTION OF THE DRAWINGS

FIG. 1 is a perspective view of a combination heat sink according to the present invention.

FIG. 1A is an enlarged view of a part of the combination heat sink according to the present invention.

FIG. 2 is an elevational view of one single radiation fin according to the present invention.

FIG. 3 is a schematic top view of the present invention, showing currents of air guided out of the combination heat sink.

FIG. 4 is a perspective view of an alternate form of the present invention, showing heat pipes connected to the radiation fins.

FIG. 5 is an exploded view of a heat sink according to the prior art.

FIG. 6 is an elevational view of one single radiation fin according to the prior art.

### DETAILED DESCRIPTION OF THE INVENTION

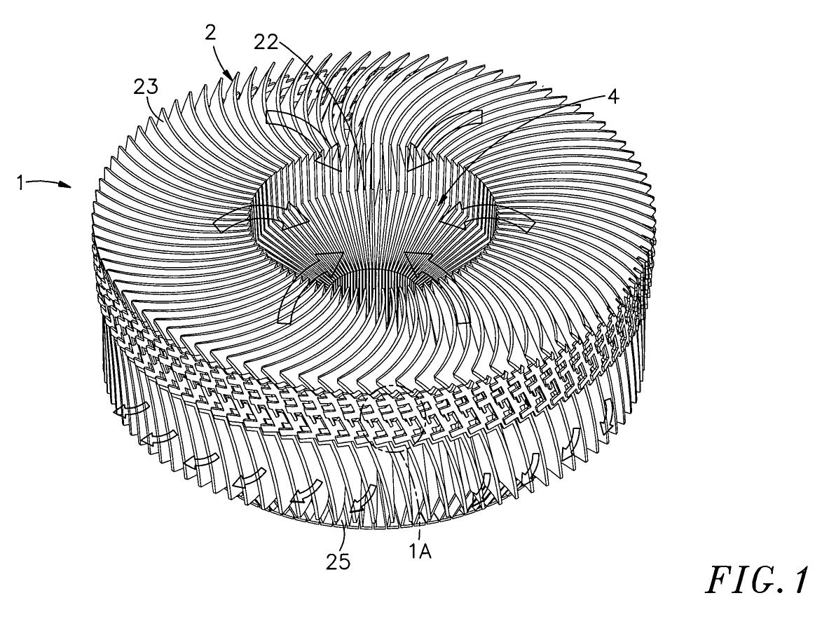

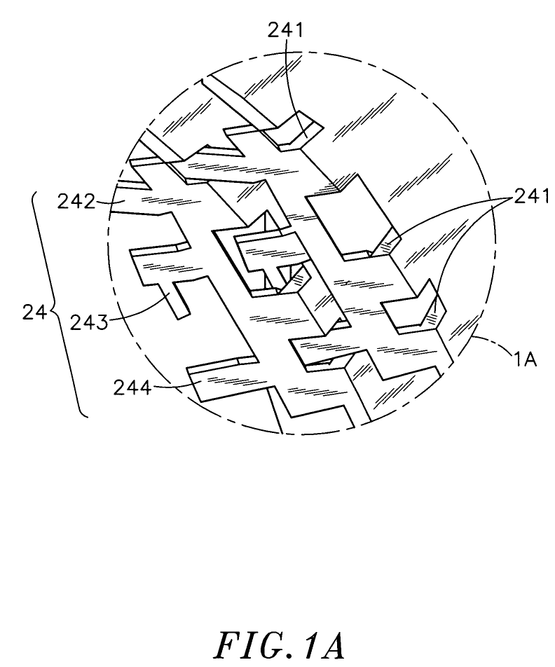

Referring to FIGS. 1 and 2, a combination heat sink 1 in accordance with the present invention is shown comprised of a plurality of radiation fins 2.

Each radiation fin 2 has a flat base 21, a curved surface portion 23 extending from one side, namely, the front side of the flat base 21, a notch 22 formed on the top side of the flat base 21 adjacent to the curved surface portion 23, a coupling portion 24 extending from one side of the curved surface portion 23 opposite to the flat base 21 at an angle (for example, 90-degrees), and a bonding surface portion 25 extending from the bottom side of the flat base 21 for fastening to a metal member by bonding or soldering. The coupling portion 24 comprises a plurality of through holes 241, a first fixed pin 242, a hook 243, and a second fixed pin 244. The notch 22 can be a triangular notch having a sloping side, or a chamfered notch.

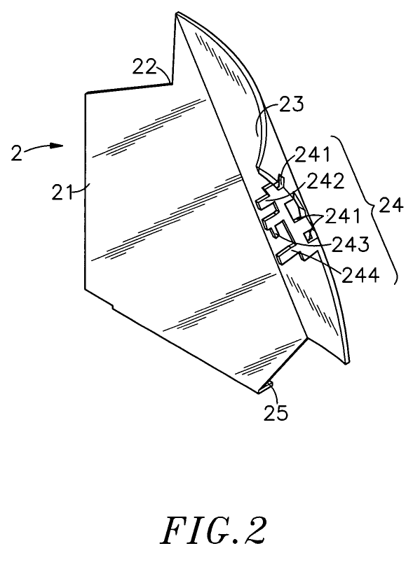

Referring to FIGS. 1A and 3 and FIGS. 1 and 2 again, by means of engaging the first fixed pin 242, the hook 243 and the second fixed pin 244 of one radiation fin 2 into the through holes 241 of another radiation fin 2, the radiation fins 2 are fastened together, showing a hollow rounded structure. When assembled, the notches 22 of the radiation fins 2 constitute a rounded recess 4 at the top side of the heat sink 1. When an external fan (not shown) is operated to cause currents of air toward the heat sink 1, the curved surface portions 23 of the radiation fins 2 guide external cold air into the rounded recess 4 rapidly, enabling cold currents of air to flow over the surface of every radiation fin 2 and to carry heat away from the radiation fins 2 efficiently. Therefore, heat can quickly be dissipated from the center area of the combination heat sink 1 to the outside open air.

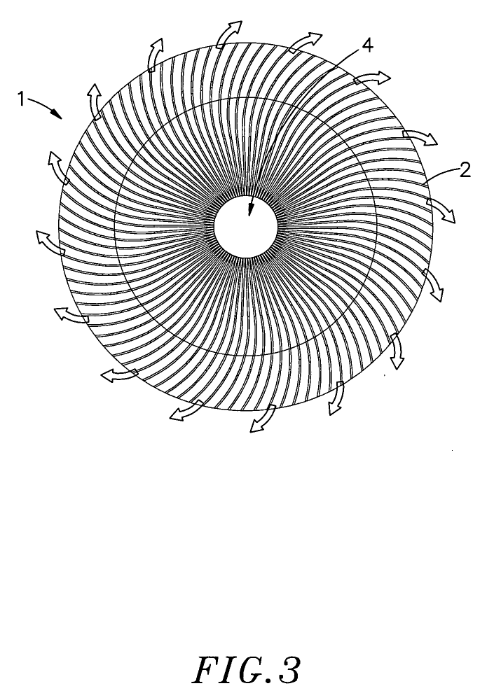

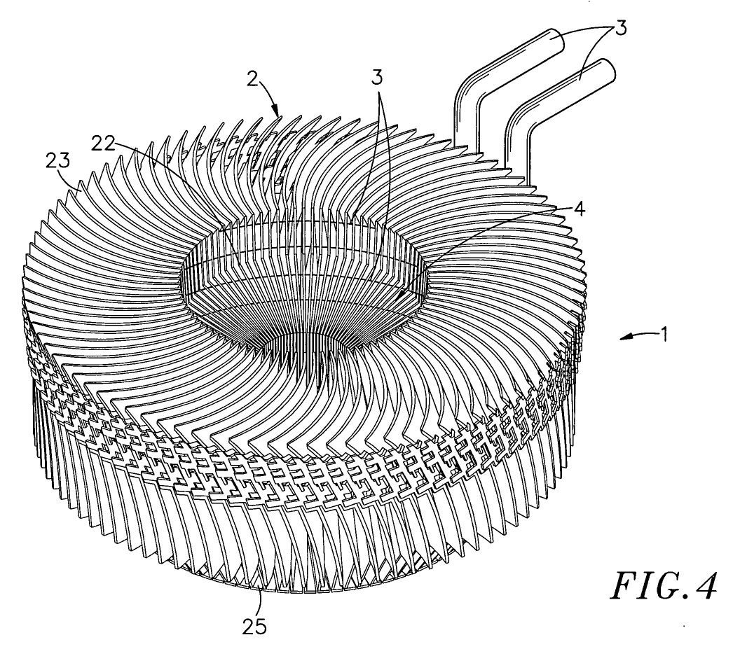

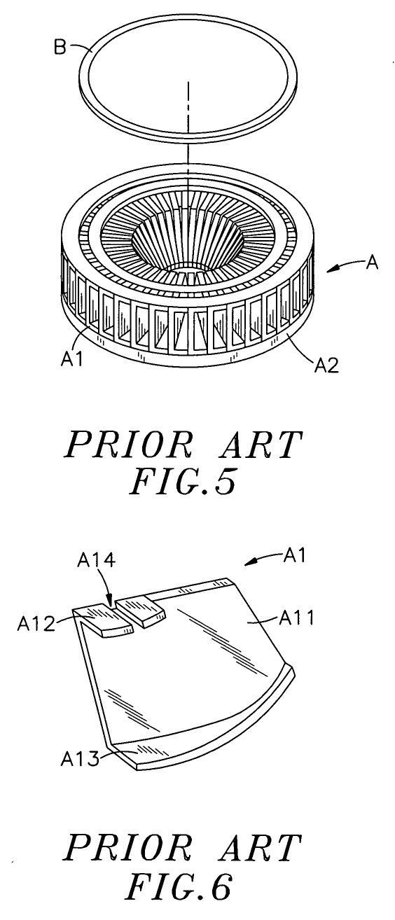

FIG. 4 shows an alternate form of the present invention. According to this embodiment, heat pipes 3 are connected to every radiation fin 2 and extending to the outside of the combination heat sink 1 for connection to external cooler means to carry heat away from the center area of the heat sink 1 rapidly.

As indicated above, the invention provides a combination heat sink, which has the following benefits:

1. By means of fastening the coupling portion 24 of one radiation fin 2 to the coupling portion 24 of another, the radiation fins 2 are fastened together to constitute the desired combination heat sink 1 without the use of any external fastening means or tool.

2. The notches 22 of the radiation fins 2 constitute a rounded recess 4 at the top side of the combination heat sink 1. The rounded recess 4 gathers the currents of air caused by the external fan, increases the wind resistance, and guides the currents of air over the surface of the radiation fins 2 to carry heat away from the combination heat sink 1 rapidly.

3. The curved surface portion 23 of each radiation fin 2 guides the currents of air caused by the external fan to circulate through the combination heat sink 1, thereby carrying heat away from the combination heat sink 1 rapidly.

4. The top side of the radiation fins 2 does not constitute a wind barrier against incident currents of air, therefore currents of air caused by the external fan can be efficiently guided over the surface of every radiation fin 2 to carry heat away from the combination heat sink 1 efficiently.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A combination heat sink comprising a plurality of radiation fins radially fastened together, said radiation fins each have a flat base and a bonding surface portion extending from a bottom side of said flat base for bonding to a metal member, wherein said radiation fins each have a curved surface portion extending from a front side of said flat base, a notch on a top side of said flat base adjacent to said curved surface portion, and a coupling portion extending from one side of said curved surface portion opposite to said flat base at an angle, said coupling portions of said radiation fins being coupled to one another such that said notches of said radiation fins constitute a rounded recess at a top side of said heat sink.

2. The combination heat sink as claimed in claim 1, wherein said coupling portion comprises a plurality of through holes, a first fixed pin, a hook, and a second fixed pin, said first fixed pin, said hook and said second fixed pin of one of said radiation fins being respectively engaged into said through holes of another of said radiation fins.

3. The combination heat sink as claimed in claim 1, further comprising at least one heat pipe connected to said radiation fins.

4. The combination heat sink as claimed in claim 1, wherein said notch of each of said radiation fins is a triangular notch having one sloping side.

5. The combination heat sink as claimed in claim 1, wherein said notch of each of said radiation fins is a chamfered notch.
